(19) United States
(12) Patent Application Publication
(10) Pub. No.: US 2025/0347736 A1
(43) Pub. Date: Nov. 13, 2025

(54) DYNAMIC BURN-IN TEST SYSTEM AND METHOD THEREOF

(71) Applicant: King Yuan ELECTRONICS CO., LTD., Hsinchu City (TW)

(72) Inventors: Tsung-Yi Lin, Hsinchu City (TW); Ming-Hsien Lee, Hsinchu City (TW); Ta-Kang Liu, Hsinchu City (TW)

(73) Assignee: King Yuan ELECTRONICS CO., LTD., Hsinchu City (TW)

(21) Appl. No.: 18/977,071

(22) Filed: Dec. 11, 2024

(30) Foreign Application Priority Data
May 13, 2024 (TW) 113117652

(51) Int. Cl. G01R 31/28

(52) U.S. Cl. CPC G01R 31/2863

(57) ABSTRACT

A dynamic burn-in test system includes at least one burn-in board, at least one signal generation module, and a dynamic adjustment module. The burn-in board is adapted for electrically connecting to a plurality of devices under test (DUTs). The signal generation module is configured to: control the DUTs to perform a test, determine at least one unqualified DUT of the DUTs in response to test results of the DUTs, transmit simulation test data to the unqualified DUT, control the unqualified DUT to execute the simulation test data to generate a simulation test result, and generate a dynamic test parameter in response to the simulation test result. The dynamic adjustment module is configured to: receive the dynamic test parameter 10 from the signal generation module, and modulate the burn-in board together with the signal generation module to perform a dynamic burn-in test on the unqualified DUT based on the dynamic test parameter.

### CROSS-REFERENCE TO RELATED APPLICATION

This non-provisional application claims priority under 35 U.S.C. § 119(a) to patent application Ser. No. 11/311,7652 filed in Taiwan, R.O.C. on May 13, 2024, the entire contents of which are hereby incorporated by reference.

### BACKGROUND

### Technical Field

The present disclosure relates to semiconductor test systems and methods, and in particular, to a burn-in test system and a burn-in test method.

### Related Art

Burn-in tests are mainly used for screening out semiconductor products in a risk of a potential chip failure or malfunction caused by poor manufacturing processes or design defects. It is detected through harsh environmental factors (for example, variables such as a high temperature or temperature difference, a high current, and a high voltage) in burn-in tests whether a chip has a defect or a failure as a result of a change in an external environment, to prevent malfunctions during use of products by terminal customers. However, in a general burn-in test architecture, a plurality of devices under test (DUTs) are usually simultaneously tested on one burn-in board, to improve test efficiency. However, a same burn-in parameter is used for different DUTs on a same burn-in board. In other words, a current burn-in test architecture cannot achieve a burn-in test fitting a specific DUT based on a specification or a status thereof, and therefore needs to be improved.

### SUMMARY

The present disclosure provides a dynamic burn-in test system, including at least one burn-in board, at least one signal generation module, and a dynamic adjustment module. The burn-in board is adapted for electrically connecting to a plurality of devices under test (DUTs). The signal generation module is electrically connected to the burn-in board, and is configured to: control the DUTs to perform a test, determine at least one unqualified DUT of the DUTs in response to test results of the DUTs, transmit simulation test data to the unqualified DUT, control the unqualified DUT to execute the simulation test data to generate a simulation test result, and generate a dynamic test parameter in response to the simulation test result. The dynamic adjustment module is electrically connected to the signal generation module and the burn-in board, and is configured to: receive the dynamic test parameter from the signal generation module, and modulate the burn-in board together with the signal generation module to perform a dynamic burn-in test on the unqualified DUT based on the dynamic test parameter.

In some embodiments, the burn-in board includes a substrate, test bases, a temperature control module, and a power control module. The test bases are electrically connected to the substrate. The temperature control module is electrically connected to the substrate, and is configured to adjust a temperature of each test base under control of the dynamic adjustment module. The power control module is electrically connected to the substrate, and is configured to adjust a voltage value outputted to each test base under control of the dynamic adjustment module.

In some embodiments, the power control module is configured to provide power with a reduced voltage value and an increased current value to each test base.

In some embodiments, the dynamic adjustment module includes a power supply module, a burn-in temperature distribution module, and a burn-in power distribution module electrically connected to each other. The power supply module is configured to supply power to the burn-in board. The burn-in temperature distribution module is configured to transmit a test temperature control signal to the temperature control module based on the dynamic test parameter to adjust the temperature of each test base. The burn-in power distribution module is configured to transmit a test power control signal to the power control module based on the dynamic test parameter to adjust the voltage value outputted to each test base.

In some embodiments, the signal generation module includes a storage module and a processor electrically connected to each other. The storage module stores a lookup table. The lookup table includes a plurality of test results and a plurality of group test parameters. The signal generation module is configured to query the lookup table for a corresponding one of the plurality of test results based on the simulation test result, and output a corresponding one of the plurality of group test parameters as the dynamic test parameter.

In some embodiments, the processor is a system on a chip (SOC), a field-programmable gate array (FPGA) chip, or a high performance computing (HPC) chip.

In some embodiments, each DUT includes a plurality of processing cores. Each processing core includes at least one temperature sensing circuit. When the unqualified DUT executes the simulation test data, the signal generation module reads a sensed value of the temperature sensing circuit as the simulation test result.

In some embodiments, a quantity of the temperature control modules corresponds to a quantity of the test bases, a quantity of the power control modules corresponds to the quantity of the test bases, and each test base is electrically connected to one temperature control module and one power control module.

In some embodiments, the dynamic burn-in test system further includes a hub and a computing host. A plurality of burn-in boards are arranged, and a plurality of signal generation modules are arranged. Each burn-in board is electrically connected to each signal generation module, and each signal generation module is electrically connected to the computing host through the hub.

A dynamic burn-in test method is provided, adapted for testing a plurality of DUTs on a burn-in board. The method includes the following steps: controlling, by a signal generation module, the DUTs to perform a test, and determining at least one unqualified DUT of the DUTs in response to test results of the DUTs; transmitting, by the signal generation module, simulation test data to the unqualified DUT, and controlling the unqualified DUT to execute the simulation test data to generate a simulation test result; generating, by the signal generation module, a dynamic test parameter in response to the simulation test result, and transmitting the dynamic test parameter to a dynamic adjustment module; and modulating, by the dynamic adjustment module, the burn-in board together with the signal generation module to perform a dynamic burn-in test on the unqualified DUT based on the dynamic test parameter.

In some embodiments, the signal generation module is configured to control each DUT to perform a function test.

In some embodiments, the simulation test result includes at least one of a voltage variation value, a current variation value, and a temperature variation value.

In some embodiments, the dynamic test parameter includes at least one of a specific voltage value and a specific current value inputted to the unqualified DUT, and controlling a temperature of the unqualified DUT to reach a specific temperature value.

In some embodiments, the signal generation module is configured to generate the dynamic test parameter by querying a lookup table based on the simulation test result.

### BRIEF DESCRIPTION OF THE DRAWINGS

FIG. 1 is a schematic block diagram of a system of an embodiment of a dynamic burn-in test system according to the present disclosure.

FIG. 2 is a flowchart of steps of an embodiment of a dynamic burn-in test method according to the present disclosure.

FIG. 3 is a schematic block diagram of a system of another embodiment of a dynamic burn-in test system according to the present disclosure.

FIG. 4 is a schematic architectural diagram of an embodiment of a signal generation module of the dynamic burn-in test system according to the present disclosure.

FIG. 5 is a schematic architectural diagram of another embodiment of a signal generation module of the dynamic burn-in test system according to the present disclosure.

FIG. 6 is a schematic diagram of an execution logic for the dynamic burn-in test system to perform a dynamic burn-in test method according to the present disclosure.

FIG. 7 is a schematic flowchart of switching a burn-in test pattern in the dynamic burn-in test method according to the present disclosure.

FIG. 8 is a schematic architectural diagram of an embodiment of a burn-in board of the dynamic burn-in test system according to the present disclosure.

FIG. 9 is a schematic flowchart of modulating a test power parameter in the dynamic burn-in test method according to the present disclosure.

FIG. 10 is a schematic flowchart of modulating a test temperature parameter in the dynamic burn-in test method according to the present disclosure.

FIG. 11 is a schematic architectural diagram of another embodiment of a burn-in board of the dynamic burn-in test system according to the present disclosure.

FIG. 12 is a schematic architectural diagram of an embodiment of a device under test (DUT) of the dynamic burn-in test system according to the present disclosure.

FIG. 13 is a schematic architectural diagram of still another embodiment of a dynamic burn-in test system according to the present disclosure.

### DETAILED DESCRIPTION

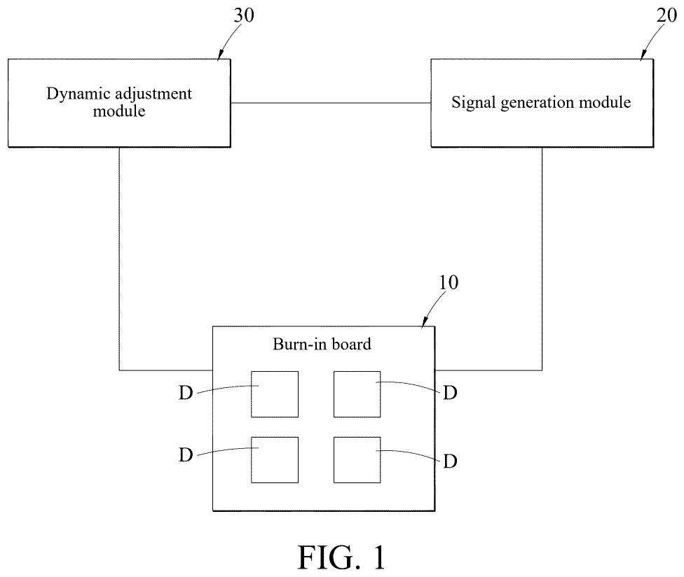

Referring to FIG. 1, the present disclosure provides a dynamic burn-in test system, including a burn-in board 10, a signal generation module 20, and a dynamic adjustment module 30. The signal generation module 20 and the dynamic adjustment module 30 operate in cooperation with each other based on simulation test results of devices under test (DUTs) D to perform dynamical burn-in test on at least one unqualified DUT D on the burn-in board 10.

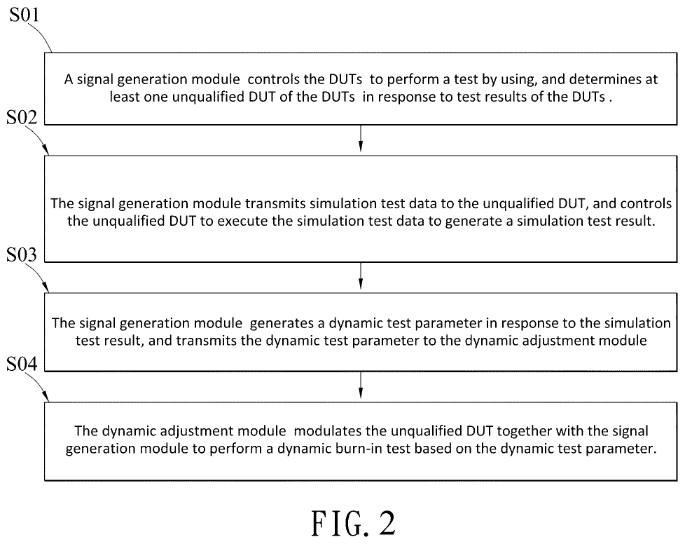

Referring to FIG. 1 and FIG. 2, the burn-in board 10 is adapted for electrically connecting to a plurality of DUTs D. The signal generation module 20 is electrically connected to the burn-in board 10, and is configured to: control the DUTs D to perform a test, determine the at least one unqualified DUT D in response to test results of the DUTs D, transmit simulation test data to the unqualified DUT D, control the unqualified DUT D to execute the simulation test data to generate a simulation test result, and generate a dynamic test parameter in response to the simulation test result. The dynamic adjustment module 30 is electrically connected to the signal generation module 20 and the burn-in board 10, and is configured to: receive the dynamic test parameter from the signal generation module 20, and modulate the burn-in board 10 together with the signal generation module 20 to perform a dynamic burn-in test on the unqualified DUT D based on the dynamic test parameter.

Referring to FIG. 1 and FIG. 2, based on the dynamic burn-in test system, the present disclosure further provides a dynamic burn-in test method, including the following steps:

Step S01: The signal generation module 20 controls the DUTs D to perform a test, and determines at least one unqualified DUT D of the DUTs D in response to test results of the DUTs D. In some embodiments, the signal generation module 20 controls the DUTs D to perform a function test, to classify the DUTs D based on function test results.

Step S02: The signal generation module 20 transmits simulation test data to the unqualified DUT D, and controls the unqualified DUT D to execute the simulation test data to generate a simulation test result.

Step S03: The signal generation module 20 generates a dynamic test parameter in response to the simulation test result, and transmits the dynamic test parameter to the dynamic adjustment module 30.

Step S04: The dynamic adjustment module 30 modulates the unqualified DUT D together with the signal generation module 20 to perform a dynamic burn-in test based on the dynamic test parameter.

Each DUT D is a semiconductor element. In some embodiments, the DUT D of the dynamic burn-in test system and the dynamic burn-in test method of the present disclosure is a high performance computing (HPC) chip. In some embodiments in which the DUT D is an HPC chip, the DUT D may be, but is not limited to, a central processing unit (CPU) chip, an HW accelerator chip (for example, a graphics processing unit (GPU) chip, a general-purpose computing on graphics processing unit (GPGPU) chip, a field-programmable gate array (FPGA) chip, a digital signal processing (DSP) chip, a tensor processing unit (TPU) chip, an artificial intelligence (AI) chip, another appropriate HW accelerator chip, or a combination thereof), a memory chip (for example, a high bandwidth memory (HBM) chip, a graphics double-data rate (GDDR) memory chip, another appropriate memory chip, or a combination thereof), an input/output (I/O) chip, a communication chip, or a power management chip.

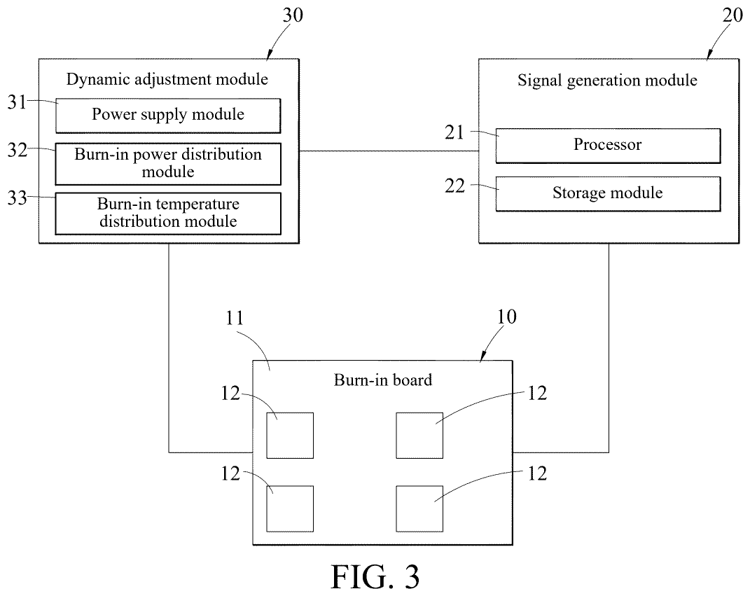

Referring to FIG. 1 and FIG. 3, in some embodiments, the burn-in board 10 includes a substrate 11 and a plurality of test bases 12. The test bases 12 are electrically connected to the substrate 11 and configured to electrically connect to the DUTs D to perform a dynamic burn-in test.

Referring to FIG. 3, in some embodiments, the signal generation module 20 includes a processor 21 and a storage module 22 electrically connected to each other. The processor 21 performs various processing required by the signal generation module 20. In some embodiments, the processor 21 may be, but is not limited to, a system on a chip (SOC), an FPGA chip, or an HPC chip.

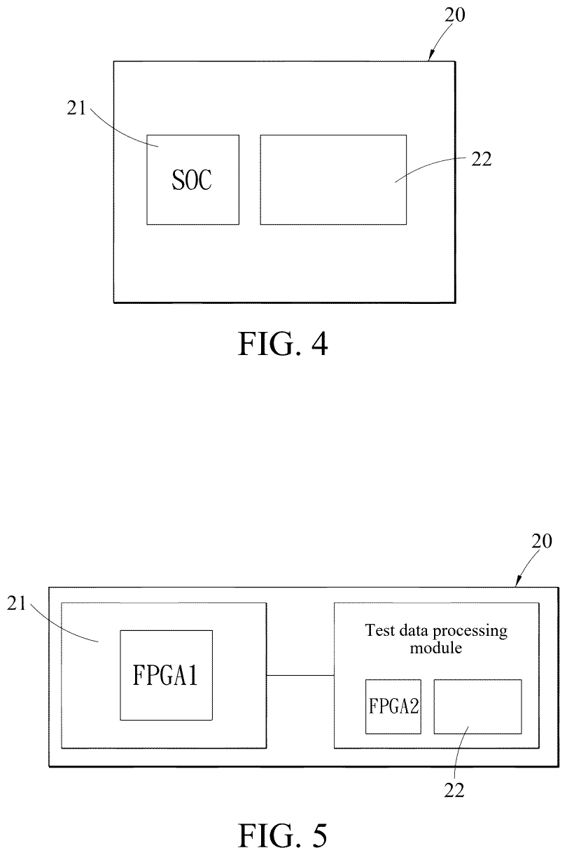

In some embodiments in which the processor 21 of the signal generation module 20 is an SOC, referring to FIG. 4, the SOC serves as the processor 21 and is integrated with the storage module 22 into a signal generation module 20 in a form of a single chip. In some embodiments in which the processor 21 of the signal generation module 20 is an FPGA, referring to FIG. 5, the FPGA includes a first FPGA (FPGA1) and a second FPGA (FPGA2). The first FPGA (FPGA1) serves as the processor 21, and the second FPGA (FPGA2) and the storage module 22 form a test data processing module. The test data processing module is electrically connected to the processor 21 to form the signal generation module 20.

The storage module 22 is configured to store test data. The test data is data that can be executed by the DUTs D. In other words, when data that can be executed by the DUTs D is different, the test data is also different. In some embodiments, the test data may be, but is not limited to, image files, text files, audio/video files, applications, or various files or data that can be executed by the DUTs D.

In some embodiments, the test data includes simulation test data and a burn-in test pattern. The simulation test data is data executed by the DUTs D during a simulation test, and the burn-in test pattern is test data executed during the dynamic burn-in test. In other words, the simulation test data is determined based on test results of the DUTs D in step S01, and the burn-in test pattern is determined based on the dynamic test parameter.

In these embodiments, the storage module 22 may pre-store a plurality of types of simulation test data and burn-in test patterns to adapt to simulation tests and the dynamic burn-in tests of different DUTs D. To be specific, the simulation test data may be, but is not limited to, files or data that can be executed by the DUTs D such as image files, text files, audio/video files, and applications.

In some embodiments, the storage module 22 may be any type of fixed or removable random access memory (RAM), a read-only memory (ROM), a flash memory, a hard disk drive (HDD), a solid state drive (SSD), a similar element, or a combination of the above elements.

Referring to FIG. 1 to FIG. 3 and FIG. 6, an execution logic of the dynamic burn-in test method of the present disclosure is to perform a simulation test when a DUT D is determined as an unqualified DUT D in step S01. In some embodiments, in step S01, the signal generation module 20 determines a DUT D as an unqualified DUT D based on a function test result, and the determination basis is determined by the signal generation module 20. In some embodiments, a determination method for determining a DUT D as an unqualified DUT D may be that conditions such as the function test result being greater than, less than, or unequal to a specific parameter are satisfied. Since a value of the specific parameter for determination may be modulated based on severity of a test, when the conditions such as the function test result being greater than, less than, or unequal to the specific parameter are satisfied, for example, a data processing time exceeds a preset specific time, a DUT D may be determined unqualified. In some embodiments, the function test result may be, but is not limited to, for example, a quantity of functions for which the DUT D has been tested and passed or failed.

Referring to FIG. 1 to FIG. 3 and FIG. 6, in step S02, the processor 21 of the signal generation module 20 accesses the simulation test data in the storage module 22 based on the test results of the DUTs D in step S01, and then transmits the simulation test data corresponding to the DUTs D to the DUTs D to perform a simulation test on the DUTs D. In some embodiments, step S01 and step S02 may be directly performed in a burn-in device, and a test environment of step S02 (the simulation test) may be the same as a test environment of step S01. In other embodiments, an environment parameter of step S01 may be canceled, for example, a high temperature is canceled, and step S02 is performed at a room temperature.

Furthermore, after the simulation test result of the DUT D is generated, the processor 21 of the signal generation module 20 receives the simulation test result, and generates the dynamic test parameter based on the simulation test result. In some embodiments, the simulation test result includes at least one of a voltage variation value, a current variation value, and a temperature variation value. In other embodiments, the simulation test result may be time spent by the DUT D in processing the test data, a thermal design power, a clock rate, or other parameters enabling identification of a function or efficiency of the DUT D.

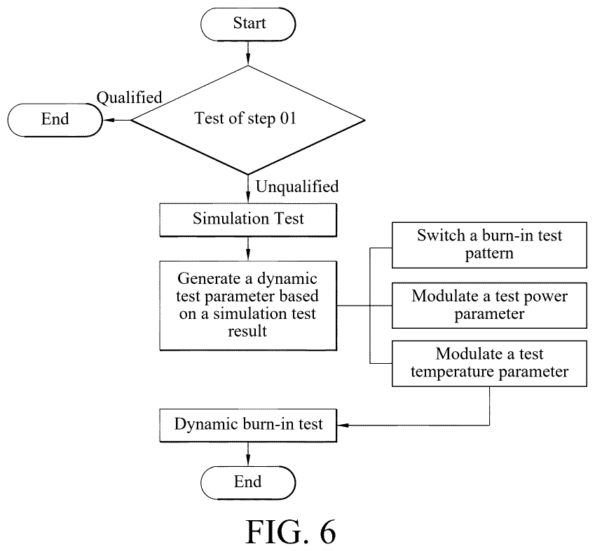

The dynamic adjustment module 30 is configured to modulate a dynamic burn-in test parameter of each unqualified DUT D on the burn-in board 10 based on the dynamic test parameter. Referring to FIG. 6, in some embodiments, the dynamic burn-in test parameter includes a burn-in test pattern, a test power parameter, and a test temperature parameter. In these embodiments, the burn-in test pattern is test content of the dynamic burn-in test, for example a test item, a test method, and a determination criterion. In some embodiments, burn-in test patterns of step S01 and step S04 may be the same. In other embodiments, the burn-in test patterns of step S01 and step S04 may be different. For example, specific test items are omitted, or determination reference values of test items are adjusted. The test power parameter is a specific voltage value and a specific current value inputted to the unqualified DUT D to perform a dynamic burn-in test. The test temperature parameter is a specific test temperature for the unqualified DUT D to perform the dynamic burn-in test. In other words, in these embodiments, a specific manner in which the dynamic adjustment module 30 modulates the burn-in board 10 together with the signal generation module 20 in step S04 is modulating the burn-in test pattern, the test power parameter, and the test temperature parameter inputted to the unqualified DUT D to perform the dynamic burn-in test.

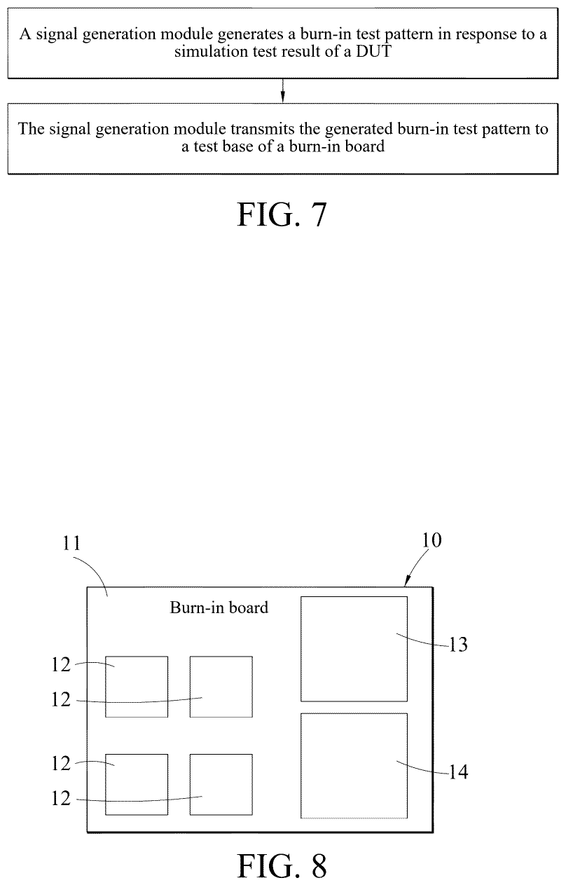

In some embodiments, a specific manner of modulating the burn-in test pattern of the unqualified DUT D is shown in FIG. 7. After the signal generation module 20 generates the dynamic burn-in test parameter in response to the simulation test result of the DUT D, the signal generation module 20 transmits a burn-in test pattern of the generated dynamic burn-in test parameter to a test base 12 of the unqualified DUT D on the burn-in board 10.

Referring to FIG. 2 and FIG. 3, in some embodiments, the dynamic adjustment module 30 includes a power supply module 31, a burn-in power distribution module 32, and a burn-in temperature distribution module 33 electrically connected to each other. In some embodiments, the power supply module 31 includes an alternating current-direct current converter configured to receive an alternating current and convert the alternating current into a direct current for output. In these embodiments, in step S04, the dynamic adjustment module 30 transmits a test power control signal to the burn-in board 10 through the burn-in power distribution module 32 based on the dynamic burn-in test parameter, and transmits a test temperature control signal to the burn-in board 10 through the burn-in temperature distribution module 33 based on the dynamic burn-in test parameter.

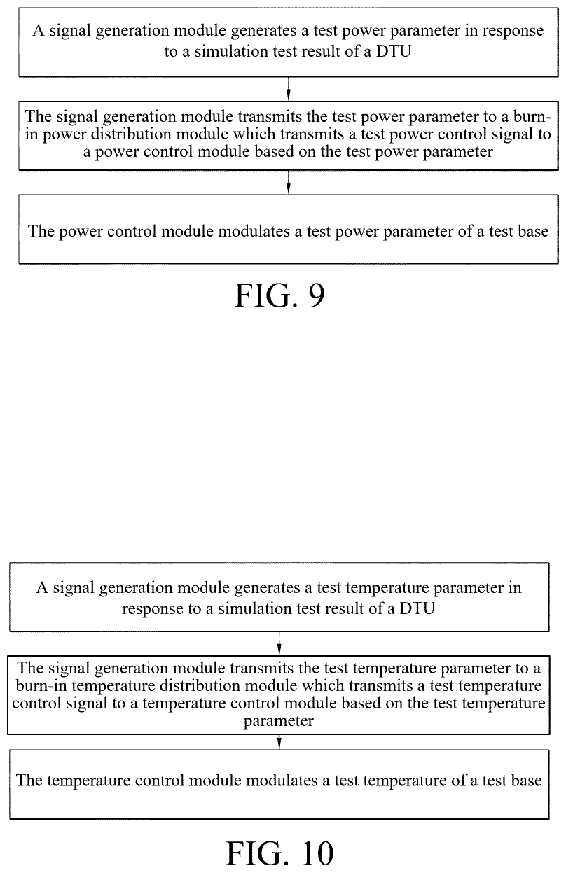

Referring to FIG. 8, in some embodiments, the burn-in board 10 further includes a power control module 13. The power control module 13 is electrically connected to the substrate 11. The power control module 13 is configured to adjust a voltage value outputted to each test base 12 based on control from the burn-in power distribution module 32 of the dynamic adjustment module 30. In some embodiments, the power control module 13 is a direct current-direct current converter, and the power supply module 31 of the dynamic adjustment module 30 supplies power to the power control module 13. In these embodiments, in step S04, a specific manner in which the dynamic adjustment module 30 modulates the test power parameter of the burn-in board 10 is shown in FIG. 9. After the signal generation module 20 generates the dynamic burn-in test parameter including the test power parameter in response to the simulation test result of the DUT D, the signal generation module 20 transmits the power test parameter to the burn-in power distribution module 32 which transmits a test power control signal to the power control module 13 of the burn-in board 10 based on the power test parameter, so that the power control module 13 of the burn-in board 10 can provide corresponding power to the test base 12 based on the test power control signal from the burn-in power distribution module 32.

In some embodiments in which the power supply module 31 includes an alternating current-direct current converter and the power control module 13 is a direct current-direct current converter, power provided by the power supply module 31 has a first voltage value and a first current value, and the power control module 13 reduces the first voltage value and increases the first current value after receiving the power provided by the power supply module 31. In this way, the dynamic burn-in test can be performed on the unqualified DUT D in the test base 12 based on the reduced voltage value and the increased current value.

Therefore, the power supply module 31 only needs to provide a common voltage value and a common current value to the burn-in board 10, and the power control module 13 on the burn-in board 10 can provide the power with the reduced voltage value and the increased current value to the test base 12. An increased quantity of DUTs D does not require a power supply module 31 with a larger current specification.

Referring to FIG. 8, in some embodiments, the burn-in board 10 further includes a temperature control module 14. The temperature control module 14 is electrically connected to the substrate 11. In these embodiments, in step S04, the temperature control module 14 of the burn-in board 10 can adjust a temperature of each test base 12, that is, a burn-in test temperature based on the temperature control signal from the burn-in temperature distribution module 33 of the dynamic adjustment module 30.

In some embodiments, in step S04, a specific manner in which the dynamic adjustment module 30 modulates the test temperature parameter of the burn-in board 10 is shown in FIG. 10. After the signal generation module 20 generates the dynamic burn-in test parameter including the test temperature parameter in response to the simulation test result of the DUT D, the signal generation module 20 transmits the test temperature parameter to the burn-in temperature distribution module 33 which transmits a test temperature control signal to the temperature control module 14 of the burn-in board 10 based on the test temperature parameter, so that the temperature control module 14 of the burn-in board 10 can change a test temperature of the test base 12 based on the test temperature control signal from the burn-in temperature distribution module 33.

In some embodiments, the temperature control module 14 may be a heater or a cooler. In these embodiments, the temperature control module 14 is arranged at a position corresponding to each test base 12, but the present disclosure is not limited thereto.

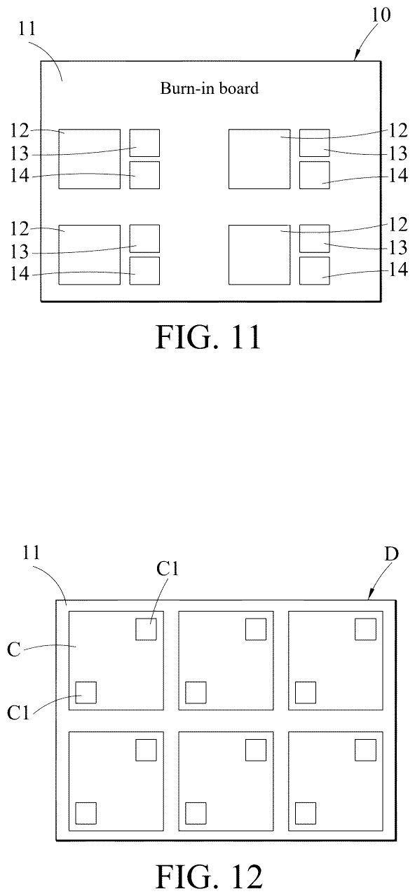

Referring to FIG. 8 and FIG. 11, in some embodiments in which the burn-in board 10 includes the power control module 13, one or more power control modules 13 may be arranged. When one power control module 13 is arranged (as shown in FIG. 8), the power control module 13 is electrically connected to all of the test bases 12 on the burn-in board 10, and power parameters of all of the test bases 12 are controlled through the single power control module 13. When a plurality of power control modules 13 are arranged (as shown in FIG. 11), a quantity of the power control modules 13 is the same as the quantity of the test bases 12. Each power control module 13 is electrically connected to one test base 12, and the power parameter of each test base 12 is controlled by a corresponding single power control module 13.

Referring to FIG. 8 and FIG. 11, in some embodiments in which the burn-in board 10 includes the temperature control module 14, one or more temperature control modules 14 may be arranged. When one temperature control module 14 is arranged (as shown in FIG. 8), the temperature control module 14 is electrically connected to all of the test bases 12 on the burn-in board 10, and temperature parameters of all of the test bases 12 are controlled through the single temperature control module 14. When a plurality of temperature control modules 14 are arranged (as shown in FIG. 11), a quantity of the temperature control modules 14 is the same as the quantity of the test bases 12. Each temperature control module 14 is electrically connected to one test base 12, and the temperature parameter of each test base 12 is controlled by a corresponding single temperature control module 14.

In some embodiments, a manner in which the signal generation module 20 generates the dynamic test parameter based on the simulation test result may be generating the dynamic test parameter by querying a lookup table. In these embodiments, the storage module 22 stores a lookup table. The lookup table includes a plurality of test results and a plurality of group test parameters corresponding to the test results.

In these embodiments, the processor 21 of the signal generation module 20 obtains a corresponding test result by querying the lookup table based on the simulation test result, then obtains a corresponding group test parameter by querying the lookup table based on the test result, and finally outputs the obtained group test parameter to the dynamic adjustment module 30 as the dynamic test parameter.

In some embodiments, a relationship between the test result and the group test parameter in the lookup table may include, but is not limited to, a single simulation test result corresponding to a single group test parameter, a single simulation test result corresponding to a plurality of group test parameter, a plurality of simulation test results corresponding to a single group test parameter, or a plurality of simulation test results corresponding to a plurality of group test parameters.

To be specific, an example in which a single simulation test result corresponds to a single group test parameter may be as follows: when a voltage variation value (a simulation test result) is consistent with a preset value (a test result), the group test parameter may be modulating a test voltage parameter inputted to the test base 12, an example in which a single simulation test result corresponds to a plurality of group test parameters may be as follows: when the voltage variation value (the simulation test result) is consistent with the preset value (the test result), the group test parameters are simultaneously switching a burn-in test pattern inputted to the test base 12 and modulating a test voltage parameter inputted to the test base 12, an example in which a plurality of simulation test results correspond to a single group test parameter may be as follows: when both the voltage variation value (the simulation test result) and a temperature variation value (a simulation test result) are consistent with preset values (test results), the group test parameter may be switching a burn-in test pattern inputted to the test base 12, and an example in which a plurality of simulation test results correspond to a plurality of group test parameters may be as follows: when both the voltage variation value (the simulation test result) and a current variation value (a simulation test result) are consistent with preset values (test results), the group test parameters are simultaneously switching a burn-in test pattern inputted to the test base 12 and modulating a test temperature parameter inputted to the test base 12. However, the above setting of the test result and the group test parameter is merely an example, and the present disclosure is not limited thereto.

In some embodiments, a plurality of lookup tables are stored in the storage module 22. The lookup tables may correspond to different DUTs D, different simulation test data, or different simulation test data groups.

In some embodiments in which the lookup tables correspond to different DUTs D, a corresponding lookup table varies with a DUT D of a different type or specification. In this case, when a DUT D varies, a test result and a corresponding group test parameter in a lookup table vary correspondingly.

In some embodiments in which the lookup tables correspond to different simulation test data, a corresponding lookup table varies with simulation test data executed by a DUT D. In this case, when simulation test data executed by the DUT D varies, a test result and a corresponding group test parameter in the lookup table vary correspondingly.

In some embodiments in which the lookup tables correspond to different simulation test data groups, a corresponding lookup table varies when simulation test data executed by a DUT D belongs to the different simulation test data groups including a plurality of pieces of simulation test data. In this case, when the simulation test data executed by the DUT D belongs to different simulation test data groups, a test result and a corresponding group test parameter in the lookup table vary correspondingly. However, the above setting of the lookup table is merely an example, and the present disclosure is not limited thereto.

It is worth noting that, a manner in which the signal generation module 20 generates the dynamic test parameter based on the simulation test result is not limited to the generation through the lookup table shown in the above embodiment. In some other implementations, the signal generation module 20 may calculate the dynamic test parameter based on a specific equation.

In some embodiments, for different DUTs D, the temperature variation value of the simulation test result may be, but is not limited to, a case temperature (Tc), a junction temperature (Tj), or a working core temperature of a DUT D.

The case temperature of the DUT D is a surface temperature of a case of the DUT D, and may be sensed through a surface temperature sensor arranged on a surface of the DUT.

The junction temperature of the DUT D is an actual working temperature of the DUT D, and may be calculated based on a sensed ambient temperature (Ta) and a known thermal resistance (θj−a) and consumed power (P[W]) of the DUT through an equation (Tj=Ta+θj−a×P[W]) for calculating the junction temperature.

Overall, different from existing technologies in which unqualified DUTs D are directly abandoned after step S01, in some embodiments, the simulation test in step S02 may be re-performed on the unqualified DUTs D, a dynamic test parameter for re-performing burn-in of each unqualified DUT D may be modulated based on a simulation test result of each unqualified DUT D, and burn-in is re-performed. A processing range of the dynamic test parameter includes but is not limited to dynamic calculation of an upper power supply limit of a test, dynamic modulation of power supply and a protection range, providing a test programs, an output state, a temperature, and a voltage, automatic hottest area switching, and automatic control of a case temperature, a junction temperature, or a core temperature of a DUT D.

The working core temperature of the DUT D is an actual working temperature of each processing core C of the DUT D including a plurality of processing cores C. Referring to FIG. 3 and FIG. 12, in these embodiments, the DUT D includes a plurality of processing cores C. Each processing core C includes at least one temperature sensing circuit C1. When the DUT D executes the simulation test data, the signal generation module 20 reads a sensed temperature value of the temperature sensing circuit Cl of each processing core C of the DUT D as the simulation test result. When the DUT D includes a plurality of processing cores C and executes simulation test data with high complexity, the signal generation module 20 can directly read a working core temperature of each processing core C. In this way, precision of temperature determination and precision of subsequent dynamic modulation are increased.

Next, the processor 21 of the signal generation module 20 generates a dynamic test parameter for each processing core C of the DUT D based on the simulation test result, and the dynamic adjustment module 30 modulates a dynamic burn-in test parameter of each processing core C of each unqualified DUT D on the burn-in board 10 based on the dynamic test parameter. The parameter is, but is not limited to, for example, a proper test voltage and temperature of each processing core C, to prevent overheating during burn-in of each processing core C. In other words, in these embodiments, a test parameter (for example, a voltage and a temperature) of each processing core may be dynamically adjusted for a simulation test result of each processing core C on each DUT D.

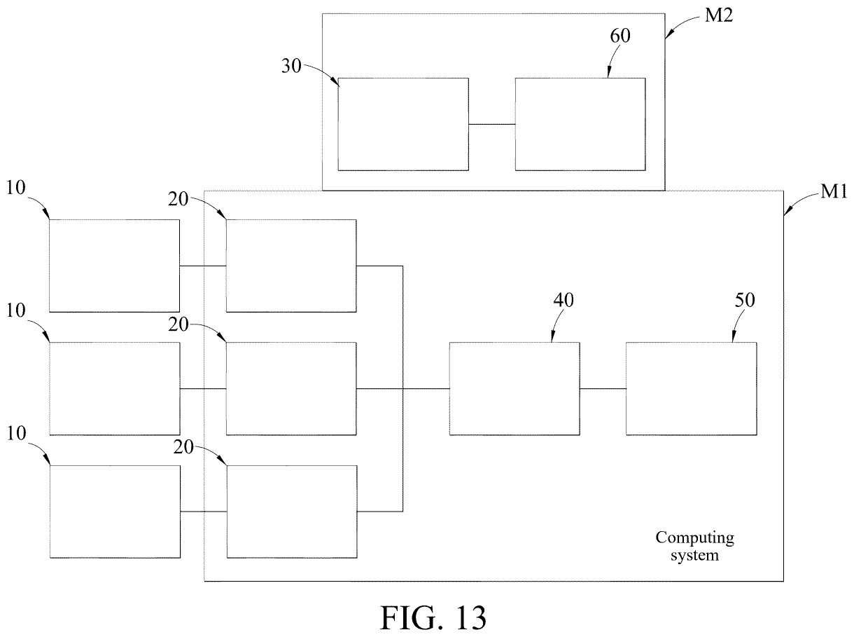

Referring to FIG. 13, in some embodiments, the dynamic burn-in test system further includes a hub 40, a computing host 50, and a burn-in host 60. In these embodiments, a plurality of signal generation modules 20 are arranged. Each signal generation module 20 is electrically connected to the computing host 50 through the hub 40 to form a computing system. The dynamic adjustment module 30 is electrically connected to the burn-in host 60 to form a burn-in test system. The computing system is electrically connected to the burn-in test system and is configured to perform burn-in on a plurality of burn-in boards 10. Herein, a plurality of burn-in boards 10 are arranged, and each burn-in board 10 is electrically connected to one signal generation module 20. In this way, the computing system and the burn-in test system perform cooperative calculation to perform dynamic burn-in test on the plurality of burn-in boards 10.

Referring to FIG. 13, in some embodiments, the dynamic burn-in test system may be integrated into a single hardware architecture. For example, the computing system is integrated into a first body M1, and the burn-in test system is integrated into a second body M2 and arranged on the first body M1 of the computing system, so as to shorten a connection line between the computing system and the burn-in test system as much as possible, thereby adapting to an operating environment of high-speed transmission and high-speed computing more effectively.

What is claimed is:

1. A dynamic burn-in test system, comprising:
at least one burn-in board, adapted for electrically connecting to a plurality of devices under test (DUTs);
at least one signal generation module, electrically connected to the at least one burn-in board and configured to: control the DUTs to perform a test, determine at least one unqualified DUT of the DUTs in response to test results of the DUTs, transmit simulation test data to the at least one unqualified DUT, control the at least one unqualified DUT to execute the simulation test data to generate a simulation test result, and generate a dynamic test parameter in response to the simulation test result; and
a dynamic adjustment module, electrically connected to the at least one signal generation module and the at least one burn-in board and configured to: receive the dynamic test parameter from the at least one signal generation module, and modulate the at least one burn-in board together with the signal generation module to perform a dynamic burn-in test on the at least one unqualified DUT based on the dynamic test parameter.

2. The dynamic burn-in test system according to claim 1, wherein the at least one burn-in board comprises:
a substrate;
a plurality of test bases, electrically connected to the substrate;
a temperature control module, electrically connected to the substrate and configured to adjust a temperature of each test base under control of the dynamic adjustment module; and
a power control module, electrically connected to the substrate and configured to adjust a voltage value outputted to each test base under control of the dynamic adjustment module.

3. The dynamic burn-in test system according to claim 2, wherein the power control module is configured to provide power with a reduced voltage value and an increased current value to each test base.

4. The dynamic burn-in test system according to claim 2, wherein the dynamic adjustment module comprises a power supply module, a burn-in temperature distribution module, and a burn-in power distribution module electrically connected to each other, the power supply module is configured to supply power to the at least one burn-in board, the burn-in temperature distribution module is configured to transmit a test temperature control signal to the temperature control module based on the dynamic test parameter to adjust the temperature of each test base, and the burn-in power distribution module is configured to transmit a test power control signal to the power control module based on the dynamic test parameter to adjust the voltage value outputted to each test base.

5. The dynamic burn-in test system according to claim 1, wherein the at least one signal generation module comprises a storage module and a processor electrically connected to each other, the storage module stores a lookup table, the lookup table comprises a plurality of test results and a plurality of group test parameters, and the at least one signal generation module is configured to query the lookup table for a corresponding one of the plurality of test results based on the simulation test result, and output a corresponding one of the plurality of group test parameters as the dynamic test parameter.

6. The dynamic burn-in test system according to claim 5, wherein the processor is a system on a chip (SOC), a field-programmable gate array (FPGA) chip, or a high performance computing (HPC) chip.

7. The dynamic burn-in test system according to claim 1, wherein each DUT comprises a plurality of processing cores, each processing core comprises at least one temperature sensing circuit, and when the at least one unqualified DUT executes the simulation test data, the at least one signal generation module reads a sensed value of the at least one temperature sensing circuit as the simulation test result.

8. The dynamic burn-in test system according to claim 2, wherein a quantity of the temperature control modules corresponds to a quantity of the test bases, a quantity of the power control modules corresponds to the quantity of the test bases, and each test base is electrically connected to one temperature control module and one power control module.

9. The dynamic burn-in test system according to claim 1, further comprising a hub and a computing host, wherein the at least one burn-in board comprises a plurality of burn-in boards, the at least one signal generation module comprises a plurality of signal generation modules, the plurality of burn-in boards are respectively electrically connected to the plurality of signal generation modules, and the plurality of signal generation modules are electrically connected to the computing host through the hub.

10. A dynamic burn-in test method, adapted for testing a plurality of DUTs on a burn-in board, the method comprising:
controlling, by a signal generation module, the DUTs to perform a test, and determining at least one unqualified DUT of the DUTs in response to test results of the DUTs;
transmitting, by the signal generation module, simulation test data to the at least one unqualified DUT, and controlling the at least one unqualified DUT to execute the simulation test data to generate a simulation test result;
generating, by the signal generation module, a dynamic test parameter in response to the simulation test result, and transmitting the dynamic test parameter to a dynamic adjustment module; and
modulating, by the dynamic adjustment module, the burn-in board together with the signal generation module to perform a dynamic burn-in test on the at least one unqualified DUT based on the dynamic test parameter.

11. The dynamic burn-in test method according to claim 10, wherein the signal generation module is configured to control the DUTs to perform a function test.

12. The dynamic burn-in test method according to claim 10, wherein the simulation test result comprises at least one of a voltage variation value, a current variation value, and a temperature variation value.

13. The dynamic burn-in test method according to claim 10, wherein the dynamic test parameter comprises at least one of a specific voltage value and a specific current value inputted to the unqualified DUT, and controlling a temperature of the unqualified DUT to reach a specific temperature value.

14. The dynamic burn-in test method according to claim 10. wherein the signal generation module is configured to generate the dynamic test parameter by querying a lookup table based on the simulation test result.
